(19) United States
(12) Patent Application Publication
(10) Pub. No.: US 2006/0124588 A1
(43) Pub. Date: Jun. 15, 2006

(54) System and method for reducing metal oxides with hydrogen radicals

(75) Inventors: Al DePetrillo, San Jose, CA (US); Craig Heden, San Jose, CA (US); Mickey McGuire, Aptos, CA (US); Ronny Bar-Gadda, Palo Alto, CA (US)

Correspondence Address: MARTINE PENILLA & GENCARELLA, LLP, 710 LAKEWAY DRIVE, SUITE 200, SUNNYVALE, CA, 94085, US

(73) Assignee: Berg & Berg Enterprises, LLC, Cupertino, CA (US)

(21) Appl. No.: 11/193,819

(22) Filed: Jul. 28, 2005

Related U.S. Application Data
(63) Continuation-in-part of application No. 10/404,216, filed on Mar. 31, 2003.
(63) Continuation-in-part of application No. 10/373,895, filed on Feb. 25, 2003, now Pat. No. 7,033,952.
Application No. 10/404,216 is a continuation-in-part of application No. 09/225,922, filed on Jan. 5, 1999, now Pat. No. 6,579,805.
Application No. 10/373,895 is a continuation-in-part of application No. 09/225,922, filed on Jan. 5, 1999, now Pat. No. 6,579,805.

(51) Int. Cl. C23F 1/00; H01L 21/306

(52) U.S. Cl. 216/67; 156/345.24; 156/345.26

(57) ABSTRACT

A method of removing impurities in a film is disclosed. The method includes generating hydrogen radicals including inputting a hydrogen radical precursor material to a radical source including a plasma chamber, that is external to a processing chamber, the radical source having an outlet in fluid communication with the processing chamber and creating a plasma in the plasma chamber. The hydrogen radicals are input into the processing chamber from the outlet of the radical source. The processing chamber has a pressure of between about 1 millitorr and about 10 torr and an impurity-containing film on a target is exposed to the hydrogen radicals. A system for reducing an oxide in an exposed surface is also disclosed.

### CROSS REFERENCE TO RELATED APPLICATIONS

This application is a continuation-in-part of and claims priority from U.S. patent application Ser. No. 10/404,216 filed on Mar. 31, 2003 and entitled “Remote ICP Torch for Semiconductor Processing,” and U.S. patent application Ser. No. 10/373,895 filed on Feb. 25, 2003 and entitled “Apparatus and Method Using a Remote RF Energized Plasma for Processing Semiconductor Wafers,” both of which are incorporated herein by reference in their entirety and both of which are continuation-in-part applications of U.S. Pat. No. 6,579,805, filed Jan. 5, 1999, which is also incorporated by reference in its entirety.

### BACKGROUND

This invention pertains generally to the fabrication of semiconductor devices and, more particularly, to a method and apparatus for the reduction of metal oxides and removal of trace contaminant elements in thin films.

Metallic (e.g., copper, aluminum, alloys, etc.) thin films, devices and structures are commonly formed in the semiconductor manufacturing process. Due to elemental contaminants (e.g., oxygen, water, chlorine, etc.) present in the deposition chamber or present in the precursor materials to the films being deposited, oxides and other undesirable contaminant-containing compounds form during the deposition process. The deposition process is normally performed at elevated temperatures. Such oxides and other undesirable contaminant-containing compounds may also form during subsequent operations performed on the deposited film. By way of example, an etching process or a chemical mechanical planarization (CMP) process can cause or allow the oxides and other undesirable contaminant-containing compounds to form. In virtually all cases, such oxides and contaminant-containing compounds are undesirable and must be removed prior to further thin film depositions.

Typically, the oxides and contaminant-containing compounds are removed from the metallic films, devices and structures by heating the metallic structures to about 450 degrees C. in the presence of a dilute hydrogen/nitrogen mixture (e.g., a “forming gas” such as a mixture of about 10% hydrogen and about 90% nitrogen) at atmospheric pressure in a chamber for a period of time. As the metallic structures are heated, the oxides and contaminant-containing compounds react with the hydrogen in the forming gas to form volatile compounds. The volatile compounds are then removed from the process chamber.

Unfortunately, this heating can cause additional problems with the semiconductor substrate. By way of example, if a previous layer includes an implanted region then the implanted species (e.g., an ion) in the implanted region can be converted to other species or dispersed further into the surrounding materials causing various well known structural and operational deficiencies. As a result, the thermal budget (i.e., the total amount of thermal energy the semiconductor is exposed to during the manufacturing process) is very strictly limited and controlled. Reducing the portion of the thermal budget consumed by any one process is a constant goal.

In view of the foregoing, it is advantageous to provide a system and a method that can substantially eliminate the oxides and contaminant-containing compounds from the deposited film, device or structure while reducing the consumption of the thermal budget of the semiconductor.

### SUMMARY OF THE INVENTION

Broadly speaking, the present invention fills these needs by providing an improved chemical generator. It should be appreciated that the present invention can be implemented in numerous ways, including as a process, an apparatus, a system, computer readable media, or a device. Several inventive embodiments of the present invention are described below.

One embodiment that provides a method of removing impurities in a film is disclosed. The method includes generating hydrogen radicals including inputting a hydrogen radical precursor material to a radical source including a plasma chamber, that is external to a processing chamber, the radical source having an outlet in fluid communication with the processing chamber and creating a plasma in the plasma chamber. The hydrogen radicals are input into the processing chamber from the outlet of the radical source. The processing chamber has a pressure of between about 1 millitorr and about 10 torr and an impurity-containing film on a target is exposed to the hydrogen radicals.

The surface of the target has a temperature of between about 50 degrees C. and about 500 degrees C. Alternatively, the surface of the target has a temperature of less than about 200 degrees C.

Inputting the hydrogen radicals into the processing chamber can optionally include cooling the hydrogen radicals. The hydrogen radicals can be input into the processing chamber at a flow rate of between about 50 sccm and about 3000 sccm.

The outlet of the radical source can be less than about 40 cm from the surface of the target. Inputting the hydrogen radicals into the processing chamber can include substantially directing the hydrogen radicals toward the impurity-containing film on the target. Inputting the hydrogen radicals into the processing chamber can include substantially evenly dispersing the hydrogen radicals over the impurity-containing film on the target.

The impurity in the impurity-containing film can include at least one oxide and exposing an impurity-containing film on a target to the hydrogen radicals can includes reducing the oxygen from the oxide. The impurity-containing film can include at least one of sulfur or a sulfur-containing compound, and exposing an impurity-containing film on the target to the hydrogen radicals can include substantially removing the at least one of the sulfur or the sulfur-containing compound. The impurity-containing film can include at least one of chlorine or a chlorine-containing compound, and exposing an impurity-containing film on the target to the hydrogen radicals can include substantially removing the at least one of the chlorine or the chlorine-containing compound. The impurity-containing film can include at least one of fluorine or a fluorine-containing compound, and exposing an impurity-containing film on the target to the hydrogen radicals includes substantially removing the at least one of the fluorine or the fluorine-containing compound.

The impurity-containing film can have a thickness of between 0 and about 500 angstroms. The impurity-containing film on the target is exposed to the hydrogen radicals for a time interval of between less than about 30 seconds to about 2 hours.

The target can be a semiconductor wafer. The impurity-containing film can include at least one of a copper or a copper alloy. The impurity-containing film can include a metal oxide.

Another embodiment provides a system for removing impurities in impurity-containing film. The system includes a processing chamber for processing at least one target, the target having an exposed impurity-containing film. A radical source is also included. The radical source being external from the processing chamber. The radical source including an inlet, a plasma chamber and an outlet, the outlet being fluidly coupled to the processing chamber. At least one precursor source is coupled to the inlet of the radical source. A controller is coupled to the radical source and the processing chamber. The controller including computer readable code for generating hydrogen radicals in the radical source including computer readable code for inputting a hydrogen radical precursor material from the at least one precursor source to the plasma chamber, computer readable code for creating a plasma in the plasma chamber and computer readable code for inputting the hydrogen radicals into the processing chamber from the outlet of the plasma chamber. The processing chamber has a pressure of between about 1 millitorr and about 10 torr and computer readable code for exposing the impurity-containing film on the target to the hydrogen radicals.

The surface of the target can have a temperature of between about 50 degrees C. and about 500 degrees C. Alternatively, the surface of the target can have a temperature of less than about 200 degrees C.

The hydrogen radicals can be input into the processing chamber at a flow rate of between about 50 sccm and about 3000 sccm. The outlet of the radical source can be less than about 40 cm from the oxide-containing film on the target.

Inputting the hydrogen radicals into the processing chamber can include substantially directing the hydrogen radicals toward the impurity-containing film on the target. Inputting the hydrogen radicals into the processing chamber can include substantially evenly dispersing the hydrogen radicals over the impurity-containing film on the target.

The impurity in the impurity-containing film can include at least one oxide and exposing an impurity-containing film on the target to the hydrogen radicals includes reducing the oxygen from the oxide. The impurity in the impurity-containing film can include at least one of sulfur, a sulfur-containing compound, and exposing the impurity-containing film on the target to the hydrogen radicals can include substantially removing the at least one of the sulfur or the sulfur-containing compound in the impurity-containing film. The impurity in the impurity-containing film can include at least one of chlorine or a chlorine-containing compound, and exposing the impurity-containing film on the target to the hydrogen radicals can include substantially removing the at least one of the chlorine or the chlorine-containing compound in the impurity-containing film. The impurity in the impurity-containing film can include at least one of fluorine or a fluorine-containing compound, and exposing the impurity-containing film on the target to the hydrogen radicals can include substantially removing the at least one of the fluorine or the fluorine-containing compound in the impurity-containing film.

The oxide layer can have a thickness of between 0 and about 500 angstroms. The surface of the target can be exposed to the hydrogen radicals for a time interval of between less than about 30 seconds to about 2 hours.

The radical source can include a first plasma chamber including a first input coupled to a first one of the at least one precursor source and a first outlet coupled to the outlet of the radical source. The radical source can also include a second plasma chamber. The second plasma chamber being concentrically about the first plasma generating chamber and including a second input coupled to a second one of the at least one precursor source and a second outlet coupled to the outlet of the radical source. An induction coil can be disposed concentrically around the first plasma chamber and the second plasma generating chamber and an RF generator coupled to the induction coil.

The target can be a semiconductor wafer. The impurity-containing film can include at least one of a copper oxide or an oxide of a copper alloy. The impurity-containing film can include a metal oxide.

Yet another embodiment provides a method of reducing oxide in an exposed surface. The method includes generating hydrogen radicals including inputting a hydrogen radical precursor material to a radical source including a plasma chamber, that is external to a processing chamber. The radical source having an outlet in fluid communication with the processing chamber and creating a plasma in the plasma chamber and inputting the hydrogen radicals into the processing chamber from the outlet of the radical source. The outlet of the radical source is less than about 40 cm from the surface of the target, wherein the processing chamber has a pressure of between about 1 millitorr and about 10 torr. A surface of a target is exposed to the hydrogen radicals, the surface of the target having an oxide-containing film. The oxide-containing film includes at least one of a copper oxide or an oxide of a copper alloy. The surface of the target has a temperature of between about 50 degrees C. and about 500 degrees C. and the oxygen is reduced from the oxide-containing film.

Inputting the hydrogen radicals into the processing chamber can include substantially evenly dispersing the hydrogen radicals over the oxide-containing film on the target.

Other aspects and advantages of the invention will become apparent from the following detailed description, taken in conjunction with the accompanying drawings, illustrating by way of example the principles of the invention.

### BRIEF DESCRIPTION OF THE DRAWINGS

The present invention will be readily understood by the following detailed description in conjunction with the accompanying drawings.

FIG. 1 is a diagrammatic view of a chemical generator, in accordance with one embodiment of the present invention.

FIG. 2 is an enlarged cross-sectional view the chemical generator taken along line 2-2 of FIG. 1, in accordance with one embodiment of the present invention.

FIG. 3 is a flowchart of the method-operations for generating radicals, in accordance with one embodiment of the present invention.

FIG. 4A is a cross-sectional view of a wafer, in accordance with one embodiment of the present invention.

FIG. 4B is a cross-sectional view of a wafer with a subsequent layer, in accordance with one embodiment of the present invention.

FIG. 5 is a flowchart of the method-operations for reducing the oxides and contaminant-containing compounds, in accordance with one embodiment of the present invention.

FIG. 6 is a side view of a radical source and a multiple wafer processing chamber, in accordance with one embodiment of the present invention.

### DETAILED DESCRIPTION

Several exemplary embodiments for a chemical generator will now be described. It will be apparent to those skilled in the art that the present invention may be practiced without some or all of the specific details set forth herein.

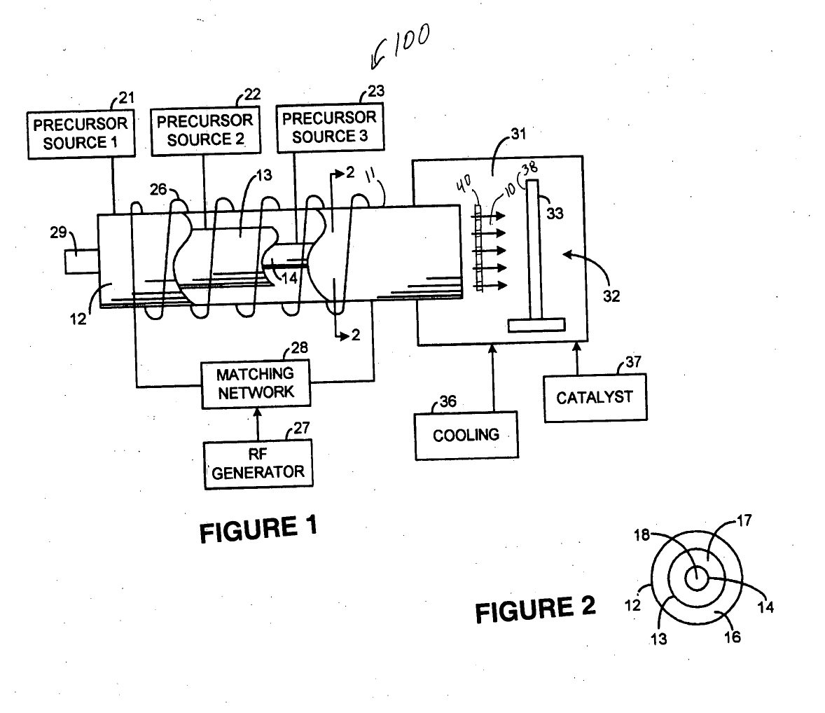

FIG. 1 is a diagrammatic view of a chemical generator 100, in accordance with one embodiment of the present invention. FIG. 2 is an enlarged cross-sectional view the chemical generator 100 taken along line 2-2 of FIG. 1, in accordance with one embodiment of the present invention. The chemical generator 100 includes a radical source 11. The radical source 11 has one or more chambers 16, 17 and 18 in which radicals 10 are created. The radicals 10 can be delivered to a processing chamber 31. In the embodiment illustrated, the radical source 11 has three chambers 16, 17 and 18 that are formed by elongated, concentric tubes 12-14.

The chambers 16, 17 and 18 include a first annular chamber 16 between the outermost tube 12 and the middle tube 13, a second annular chamber 17 between middle tube 13 and the innermost tube 14, and a third chamber 18 inside the innermost tube. The tubes 12-14 can be fabricated from any suitable material (e.g., ceramic, quartz, glass or composite).

The number of tubes 12-14 which are required in the radical source 11 is dependent upon the number of desired chemical specie to be generated and the reaction by which the desired chemical specie is formed. A separate plasma chamber 16-18 is usually, but not necessarily, provided for each type of radical to be generated in the radical source 11.

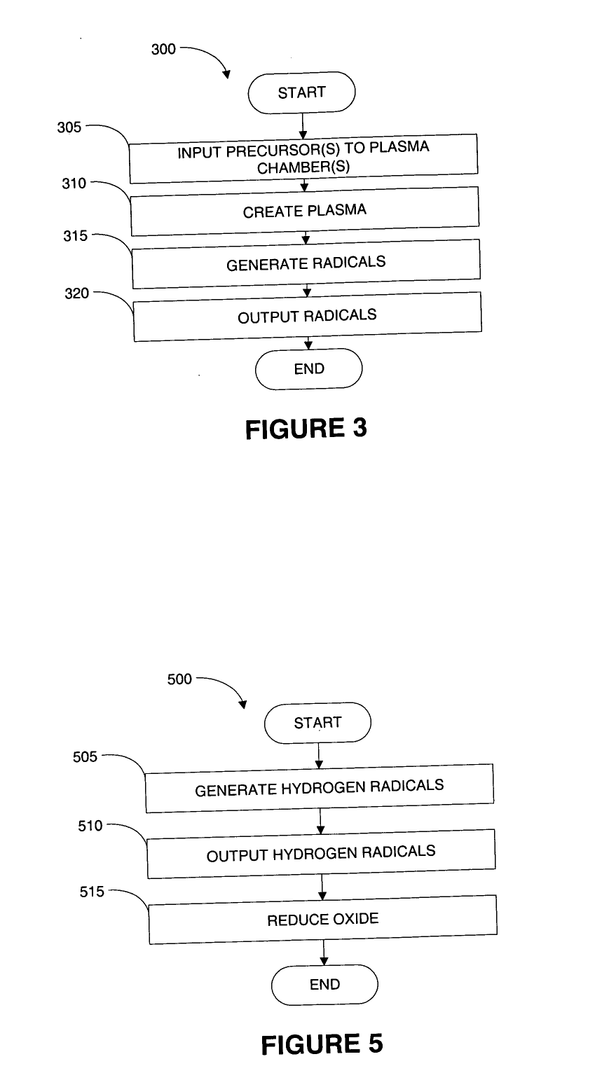

FIG. 3 is a flowchart of the method-operations 300 for generating radicals, in accordance with one embodiment of the present invention. In an operation 305, one or more gases or other precursor-compounds (precursors) from which the radicals 10 are to be formed are input to one or more of the plasma chambers 16-18. The precursors are provided from sources 21-23 or by other suitable means. The precursors can be in gaseous, liquid and/or solid form, or a combination thereof.

In an operation 310, a plasma is formed within the one or more of the chambers 16-18. The plasma can be generated by an induction coil 26 disposed concentrically about the one or more tubes 12-14. A radio frequency (RF) power generator 27 is coupled to the coil by a matching network 28. A Tesla coil 29 or other ignition source for striking an arc can also be included to ignite the plasma in the chambers 16-18. The plasma can, however, be formed by any other suitable means such as RF electrodes or microwaves. By way of example the plasma is formed within the one or more of the chambers 16-18 by applying about 200 watts to about 2000 watts of RF power through the induction coil 26. The present invention should not be limited to only induction plasma generation as other types of plasma generation could also be used.

In an operation 315, the plasma in the plasma chamber 16-18 acts on the precursor to create radicals 10. By way of example, the plasma can cause a hydrogen gas (H₂) precursor to convert to free hydrogen atoms (H₁) and/or hydrogen ions (H+ or H−).

In an operation 320, the radicals 10 are output to a processing chamber 31. At least a portion of the radicals 10 can be delivered to the processing chamber 31.

The processing chamber 31 is part of a reactor 32 in which a semiconductor wafer 33 is being processed. The processing chamber 31 can also include a showerhead 40 or other disperser structure. The showerhead 40 disperses and distributes the radicals 10 flowing from the radical source 11 into the processing chamber 31. The dispersed radicals 10 are therefore substantially evenly distributed across the surface of the wafer 33.

Optionally, the radicals 10 generated in the plasma chamber 16-18 can be cooled before entering the processing chamber 31. Cooling can be effected in a number of ways, including the circulation of a coolant such as an inert gas, liquid nitrogen, liquid helium or cooled water through tubes or a coolant jacket or other suitable means in heat exchange relationship with the reacting gases. By way of example, a coolant can be flowed through chamber 16 to cool the plasmas and/or the radicals formed in plasma chambers 17 and 18.

Cooling can also be effected by passing the radicals 10 through an expansion nozzle to lower their temperature, or by the use of either a permanent magnet or an electromagnet to converge and then subsequently expand the plasma to lower its temperature. A portion of the reactor 32 or the radical source 11 or both can be cooled.

If desired, monitoring equipment such as an optical emission spectrometer can be provided for monitoring operational parameters such as species profile and radical generation.

The radical source 11 can be integrated with the reactor 32, and the species produced is formed in close proximity to the wafer 33 being processed. The radical source 11, although it can also be used in stand-alone applications as well. The radical source 11 can be added to existing process reactors as well as being constructed as an integral part of new reactors, or as a stand-alone system.

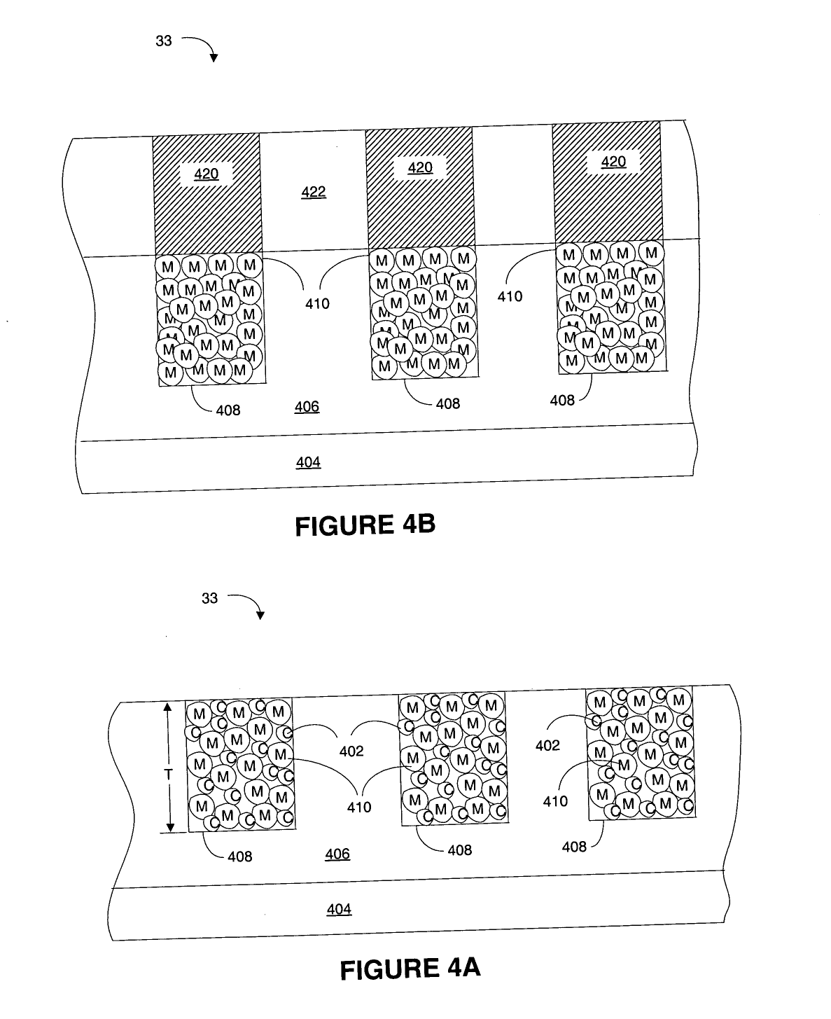

FIG. 4A is a cross-sectional view of a wafer 33, in accordance with one embodiment of the present invention. The wafer 33 has a substrate layer 404 and an intermediate layer 406. The intermediate layer 406 includes multiple features 408 that have been filled with a metallic material 410 (M) The metallic material 410 can include copper, copper alloy, or other suitable metallic materials. The metallic material 410 also includes impurities other than the metallic material. The impurities can include oxides and contaminant-containing compounds 402 (C). The metallic material 410 and oxides and contaminant-containing compounds 402 has a thickness T of about 0 (e.g., a single atomic layer) to about 500 angstroms. The contaminant-containing compounds 402 can be formed for any one of many reasons. By way ofexample, the oxides and contaminant-containing compounds 402 can be formed by exposing the metallic material 410 to oxygen or the atmosphere during transitions between manufacturing process tools. Similarly, the oxides and contaminant-containing compounds 402 can be a result of a previous manufacturing process (e.g., etching, cleaning, planarization, etc.).

FIG. 4B is a cross-sectional view of a wafer 33 with a subsequent layer 422, in accordance with one embodiment of the present invention. The impurities (i.e., the oxides and contaminant-containing compounds 402) are not desirable because the oxides and contaminant-containing compounds can reduce the effectiveness (reduced conductivity, increased resistance, etc.) of an electrical contact 420 formed in the subsequently formed layer 422. As a result, the oxides and contaminant-containing compounds 402 ideally need to be substantially removed or minimized before the subsequent layer 422 is formed over the metallic material 410 in the intermediate layer 406. As shown in FIG. 4B, the oxides and contaminant-containing compounds 402 have been removed prior to the formation of the subsequent layer 422.

FIG. 5 is a flowchart of the method-operations 500 for reducing the oxides and contaminant-containing compounds 402, in accordance with one embodiment of the present invention. In an operation 505, hydrogen radicals are generated. The hydrogen radicals can be generated in a radical source 11 as described above.

In an operation 510, the hydrogen radicals are output from the radical source 11 into the processing chamber 31. The hydrogen radicals can be dispersed through a showerhead 40. The hydrogen radicals are output from the radical source 11 and directed at the surface of the wafer 33. The output of the radical source 11 is within about 2 cm to about 40 cm from the surface of the wafer 33.

In an operation 515, the oxides are substantially reduced and the contaminant-containing compounds 402 are substantially removed. Reducing the oxides and includes drawing the oxygen atoms out of the metallic material 410 to combine with the highly reactive hydrogen radicals to form steam (i.e., H₂O). As a result of drawing the oxygen atoms out of the metallic material 410, the oxides and contaminant-containing compounds 402 are substantially reduced to leave only the metallic material 410 remaining in the features 408. In similar reactions, the contaminant-containing compounds present in contaminant-containing compounds 402 are removed. By way of example the contaminant-containing compounds 402 can include one or more of sulfur, a sulfur-containing compound, chlorine, a chlorine-containing compound, fluorine and/or a fluorine-containing compound. The hydrogen radicals can react with the sulfur, sulfur-containing compound, chlorine, chlorine-containing compound, fluorine and/or fluorine-containing compound to form volatile species that can be removed from the processing chamber 31.

Reducing the oxides and removing contaminant-containing compounds 402 does not remove significant and thereby cause a “dish” effect in the top surface of the metallic material 410 as the metallic material remains and only the oxygen atoms and the contaminant-containing compounds have been removed.

Due to the highly reactive nature of hydrogen radicals, the oxides can be reduced and contaminant-containing compounds 402 can be removed at a temperature of between about 50 and about 500 degrees C. In the prior art, the oxides are reduced through an annealing process where the wafer 33 is heated to a temperature of about 450 degrees C. or greater to drive the oxygen atoms and the contaminant-containing compounds out of the metallic material 410. Often the contaminant-containing compounds 402 are not removed in the annealing process.

As described above, reducing the portion of the thermal budget used by each manufacturing process is a constant goal. The hydrogen radicals can reduce the oxides and remove contaminant-containing compounds 402 at a much lower temperatures of between about 50 and about 200 degrees C. or somewhat higher which is substantially less than the 500 degrees C. required of the prior art annealing process. Therefore the hydrogen radicals can reduce the oxides and remove contaminant-containing compounds 402 while also significantly reducing the portion of the thermal budget used to substantially remove the oxygen atoms and the contaminant-containing compounds from the metallic material 410.

The highly reactive nature of the hydrogen radicals also allow the oxides to be reduced and contaminant-containing compounds 402 to be removed at a very low pressure of between about 1 millitorr to about 10 torr. The low pressure increases the residence time of the hydrogen radicals at the surface of the wafer 33 and thereby increases the time the hydrogen radicals are available to react with the oxygen atoms in the oxides and the contaminant-containing compounds. Prior art annealing processes are typically performed at atmospheric pressure (i.e., about 760 Torr).

Further, due to the low pressure of the oxide reduction and contaminant-containing compounds removal operation 515, the there is little to no fire or explosion hazard due to the hydrogen, even though the hydrogen radicals are highly reactive. The process chamber 31 can be constantly pumped down to remain within the about 1 millitorr to about 10 torr process conditions.

The flow rate of hydrogen radicals out of the radical generator 11 is between about 50 and about 3000 sccm. The reduction and removal operation 515 requires about 30 seconds to about 15 minutes depending on thickness of the film the oxides and contaminant-containing compounds 402 are being removed from. If the processing chamber includes multiple wafers then the oxide reduction operation 515 may require as much as about 2 hours.

By way of example, the total copper included a typical copper layer on a typical semiconductor wafer includes only about 20% elemental copper. The remaining 80% of the total copper in a typical copper layer is a combination of copper oxides (e.g., Cu₂O, CuO, Cu(OH)₂), copper sulfides (e.g., CuSO₄), copper chlorides (e.g., CuCl₂), copper fluorides (e.g., CuF₂) and copper nitrides (e.g., Cu(NO₃)₂).

In stark contrast, reducing the oxides and substantially removing the sulfur, chlorine and fluorine as described herein yields about 70% to about 85% elemental copper of the total copper in the copper layer and the remaining about 15% to about 30% of the copper remains as a combination of copper oxides, copper sulfides, copper chlorides, copper fluorides and copper nitrides. As a result the percentage of elemental copper in the copper layer is increased by a multiple of about 3.5 to about 4.

Referring again to FIG. 1 above, the radical source 11 can be aimed toward the wafer 33. By way of example in a typical, top loading processing chamber, the radical source 11 can be mounted in the cover and directed downward toward the top surface 38 of the wafer 33. Directing the flow of the radicals in a substantially straight line from the plasma chamber 18 to the top surface 38 of the wafer 33 increases the likelihood of the hydrogen radicals interacting with the surface of the oxide layer 402. The output of the radical source 11 can be close (e.g., less than about 12 inches or about 30 cm) to the target (e.g., wafer 33).

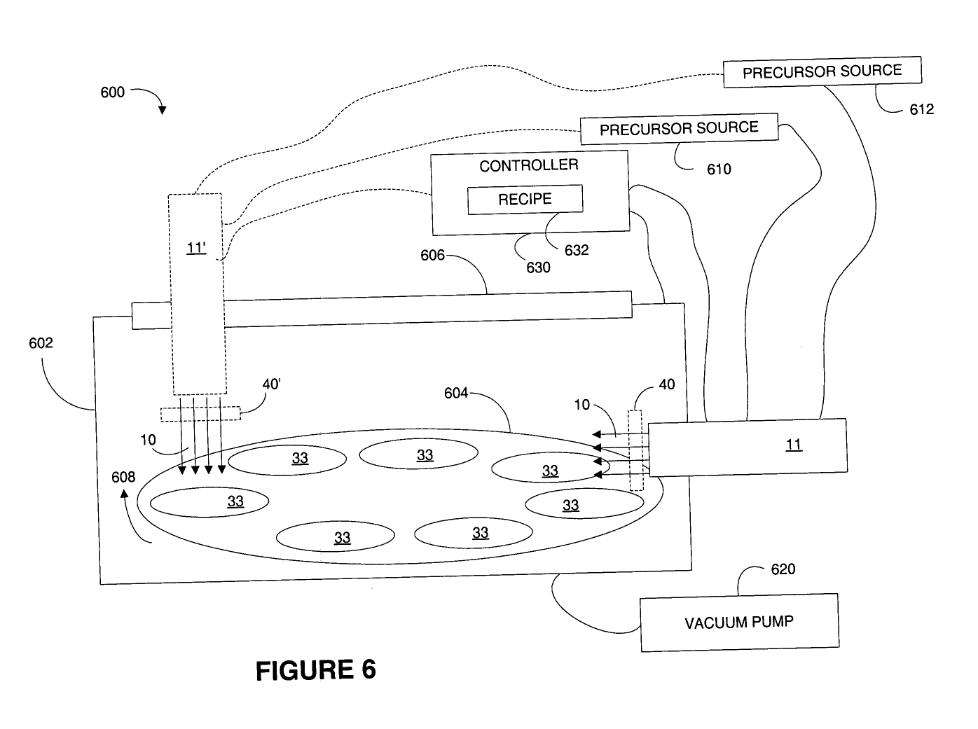

FIG. 6 is a side view of a radical source 11′ and a multiple wafer processing chamber 602, in accordance with one embodiment of the present invention. The multiple wafer processing chamber 602 includes a lid or cover 606 that can be opened to provide access for loading and unloading wafers 33. The multiple wafer processing chamber 602 also includes a platen or rotary table 604 for supporting multiple wafers 33. The rotary table 604 can rotate the wafers 33 (e.g., in direction 608) so that each of the wafers 33 can be rotated into position near the radical source 11.

The radical source 11 can be located in the side of the process chamber 602. Alternatively or additionally, the radical source 11′ can be located in the lid 606. The radical source produces radicals 10. The radical source 11 directs the radicals 10 toward the wafers 33. A showerhead 40, 40′, can also be used to disperse the radicals 10 flowing from the radical source 11, 11′. One or more precursor sources 610, 612 are coupled to the radical source 11 so as to supply precursor materials to the radical source 11. The vacuum pump 620 can reduce and maintain the pressure of the processing chamber 602 to the desired operating range.

The radical source 11′ and the multiple wafer processing chamber 602 can also include a controller 630. The controller 630 can control the radical source 11′ and the multiple wafer processing chamber 602. The controller 630 can include a recipe 632. The recipe 632 includes the operating parameters (e.g., desired set points and automatic operations including times, pressures, power levels, temperatures, flowrates, etc.) of the various semiconductor manufacturing operations conducted with the radical source 11′ and the multiple wafer processing chamber 602. The controller 630 can include a computer and the recipe 632 can be defined in computer-readable code. The controller 630 can read the computer-readable code and cause the radical source 11′ and the multiple wafer processing chamber 602, as applicable, to execute the operating parameters specified therein.

The radical source 11 can be employed in a wide variety of applications for generating different species for use in the fabrication of semiconductor devices, some examples of which are given below.

### Oxidation

The radical source 11 generate steam for use in a wet oxidation process such as may be desired for producing SiO₂ according to the reaction:
Si+H₂O→SiO₂+H₂
Admitting H₂ and O₂ into one or more of the plasma generating chambers 16-18. The H₂ and O₂ are broken down to 0 and H radicals. The O radicals (i.e., O₁ and O₃) and H radicals (i.e., H₁) can be injected into the processing chamber 31. The O and H radicals react to form steam (i.e., H₂O) in close proximity to the silicon wafer 33. The O₂ can be input alone or in a mixture with N₂ and/or Ar to produce ozone (03) such as may be desired to lower the temperature for oxidation and/or improve device characteristics of the devices being formed on the wafer 33.

NO can be used in the oxidation of silicon with O₂ to improve the device characteristics of a transistor. By way of example, the interface between silicon and silicon oxide can be improved. The interface between silicon and silicon oxide functions as a barrier to boron. Conventionally, NO is supplied to the reactor chamber 31 from a source such as a cylinder. Since NO is toxic, special precautions and handling are required to avoid leaks in the NO supply and the lines which connect the NO supply to the reactor chamber 31. Further, the purity of the NO gas is a significant factor in the final quality of the interface formed between the silicon and the silicon oxide. It is very difficult to obtain extremely pure NO.

The radical source 11 can produce highly pure NO at the point of use through the following reaction:
N₂+O₂→2NO
Admitting N₂ and O₂ to one or more of the plasma chambers 16-18 and striking a plasma. When the plasma is struck, the N₂ and O₂ form N and O radicals. The N and O radicals can be injected to the processing chamber 31. In the processing chamber 31 and in close proximity to the wafer, the N and O radicals combine to form highly pure NO. Thus, NO can be produced only when and precisely where the NO is needed, thereby substantially eliminating the need for expensive and potentially hazardous gas lines.

NO can also be produced by other reactions such as “cracking” a molecule containing only nitrogen and oxygen, such as N₂O. The NO is produced by admitting N₂O to the plasma chamber 18 by itself or with O₂. If desired, a gas such as Ar can be used as a carrier gas in order to facilitate formation of the plasma.

N₂O can be cracked either by itself or with a small amount of O₂ to form NO₂, which then dissociates to NO and O₂. In rapid thermal processing chambers and diffusion furnaces where temperatures are higher than the temperature for complete dissociation of NO₂ to NO and O₂ (620° C.), the addition of NO₂ will assist in the oxidation of silicon for gate applications where it has been found that nitrogen assists as a barrier for boron diffusion. At temperature below 650° C., a catalyst can be used to promote the conversion of NO₂ to NO and O₂. If desired, nitric acid can be generated by adding water vapor or additional H₂ and O₂ in the proper proportions.

Similarly, NH₃ and O₂ can be combined in the plasma chamber to produce NO and steam at the point of use through the following reaction:
NH₃+O₂→NO+H₂O

By using these two reagent gases, the efficacy of NO in the wet oxidation process can be mimicked.

It is often desired to include chlorine in an oxidation process because it has been found to enhance oxidation as well as gettering (i.e., trapping or removing) unwanted foreign contaminants. Using any chlorine source such as TCA or DCE, complete combustion can be achieved in the presence of O₂, yielding HCl+H₂O+CO₂. Using chlorine alone with H₂ and O₂ will also yield HCl and H₂O.

When TCA or DCE is used in oxidation processes, it is completely oxidized at temperatures above 700° C. to form HCl and carbon dioxide in reactions such as the following reaction:
C₂H₃Cl₃+2O₂→2CO₂+3HCl
C₂H₂Cl₂+2O₂→2CO₂+2HCl

The HCl is further oxidized in an equilibrium reaction:
4HCl+O₂→2H₂O+Cl₂

Decomposition of various organic chlorides with oxygen at elevated temperatures provides chlorine and oxygen-containing reagents for subsequent reactions in, e.g., silicon processing. Such decomposition is generally of the form:
CₓH_{y}Cl_{y}+xO₂→xCO₂+yHCl,
where x and y are typically 2, 3 or 4.

All of the foregoing reactions can be run under either atmospheric or subatmospheric conditions in the radical source 11. The products can be generated with or without a catalyst such as platinum.

The radical source 11 can also be employed to clean quartz tubes such as may be used for furnaces or in the selectively etching or stripping of nitride or polysilicon films from a quartz or silicon oxide layer. This is accomplished by admitting a reactant containing fluorine and chlorine such as a freon gas or liquid, i.e. CₓH_{y}F_{z}Cl_{q}. where:
x=1, 2,
y=0, 1,
z=0, 1,
q=0, 1,
and the amount of fluorine is equal to or greater than the amount of chlorine.

It is also possible to use a mixture of fluorinated gases (e.g., CHF₃, CF₄, etc.) and chlorinated liquids (e.g., CHCl₃, CCl₄, etc.) in a ratio which provides effective stripping of the nitride or polysilicon layer.

### Dielectric Films

Other dielectric films can be formed from appropriate precursor or gases. Polysilicon can be formed using SiH₄ and H₂, or silane alone. The silane may be introduced downstream of the generator to avoid nucleation and particle formation.

Silicon nitride can be formed by using NH₃ or N₂ with silane (SiH₄) or one of the higher silanes, e.g. Si₂H₆. The silane can be introduced downstream of the radical source 11 to avoid nucleation and particle formation.

In addition to gases, the radical source 11 can also use liquids and solids as starting materials, so that precursors such as TEOS can be used in the formation of conformal coatings. Ozone and TEOS have been found to be an effective mixture for the deposition of uniform layers.

### Metal and Metal Oxide Films

Metal and metal oxide films can be deposited via various precursors in accordance with the invention. For example, Ta₂O₅ films which are used extensively in memory devices can be formed by generating a precursor such as TaCl₅ via reduction of TaCl₅ followed by oxidation of the TaCl₅ to form, Ta₂O₅. In a more general sense, the precursor from which the Ta₂O₅ is generated can be expressed as TaXₘ, where X is a halogen species, and m is the stoichiometric number.

Copper can be deposited as a film or an oxide through the following reaction:
CuCl₂+H₂→Cu+HCl
Other metals can be formed in a substantially similar fashion. Instead of a gaseous precursor, a solid precursor such as Cu or another metal can also be used.

### Wafer and Chamber Cleaning

The radical source 11 can also be used to remove organic residues. By way of example, organic residue from previous process steps can be effectively removed by using the radical source 11 to convert O₂ to ozone to effectively remove the organic contaminants. In addition, reacting H₂ with an excess of O₂ will produce steam and O₂ as well as other oxygen radicals, all of which are effective in eliminating organic residue. The temperature in the process chamber 31 should be below about 700° C. if a wafer 33 is present, in order to prevent oxide formation during the cleaning process.

Sulfuric acid, nitric acid and hydrofluoric acid for use in general wafer cleaning are also effectively produced with the invention. Sulfuric acid (H₂SO₄) is generated by reacting either S, SO or S0₂ with H₂ and O₂ in accordance with the following exemplary reaction:
S+2.50₂+2H₂→H₂SO₄+H₂O
SO+1.5O₂+H₂→H₂SO₄
SO₂+1.5O₂+2H₂→H₂SO₄+H₂O
then quickly quenching the free radicals thus formed with or without a catalyst.

Nitric acid (HNO₃) is generated by reacting NH₃ with H₂ and O₂, or by the following exemplary reaction:
N₂+3.5O₂+H₂→2HNO₃+H₂O
NH₃+2O₂→2HNO₃+H₂O

Hydrofluoric acid is generated by co-reacting H₂ and O₂ with a compound containing fluorine such as NF₃ or CₓH_{y}F_{z}, where
x=1, 2,
y=0,1,
z=1, 2,

Mixed acids can be generated from a single precursor by reactions such as the following exemplary reactions:
SF₆+4H₂+2O₂→H₂SO₄+6HF
NH₂+H2+1.5O₂→HNO₃+HF
2NHF+H₂+3O₂2HNO₃+2HF
NF₃O+2H₂+O₂→HNO₃+3HF
NF₂Cl+2H₂+1.5O₂→HNO₃+2HF+HCl
N₂F₄+3H₂+3O₂→2HNO₃+4HF
N₂F₄+2H₂+3O₂→2HNO₃+2HF
NF₃+2H₂+1.5O₂→HNO₃+3HF
NF₂+1.5H₂+1.5O₂→HNO₃+2HF
NF+H₂+1.5O₂→HNO₃+HF
NS+1.5H₂+3.5O₂∴HNO₃+H₂SO₄
2N₂OF+2H₂+O₂→2HNO₃+2HF
NOF₃+2H₂+O₂→HNO₃+3HF
NOF+H₂+O₂→HNO₃+HF
NOCl+H₂+O₂→HNO₃+HCl
NOBr+H₂O+O₂→HNO₃+HBr
NO₂Cl+2H₂+O₂→2HNO₃+HCl
S₂FO+7H₂+4O₂→H₂SO₄+10HF
S₂F₂+3H₂+4O₂→H₂SO₄+2HF
SF+1.5H₂+2O₂→H₂SO₄+HF
SF₂+2H₂+2O₂→H₂SO₄+2HF
SF₃+2.5H₂+2O₂→H₂SO₄+3HF
SF₄+3H₂+2O₂→H₂SO₄+4HF
SF₅+3.5H₂+2O₂→H₂SO₄+5HF
SF₆+4H₂+2O₂→H₂SO₄+6HF
SBrFS+4H₂+2O₂→H₂SO₄+5HF+HBr
S₂Br₂+3H₂+4O₂→2H₂SO₄+2HBr
SBr₂+2H₂+2O₂→H₂SO₄+2HBr
S0₂F₂+2H₂+O₂→H₂SO₄+2HF
SOF₄+3H₂+1.5O₂→H₂SO₄+4HF
SOF₂+2H₂+1.5O₂→H₂SO₄+2HF
SOF+1.5H₂+1.5O₂→H₂SO₄+HF
SO₂ClF+2H₂+O₂→H₂SO₄+HF+HCl
SOCl₂+2H₂+1.5O₂→H₂SO₄+2HCl
SOCl₂+1.5H₂+1.5O₂→H₂SO₄+HCl
SOBr₂+2H₂+1.5O₂→H₂SO₄+2HBrCl
SF₂Cl+2.5H₂+2O₂→H₂SO₄+2HF+HCl
SCIF₅+4H₂+2O₂→H₂SO₄+5HF+HCl
SO₂Cl₂+2H₂+O₂→H₂SO₄+2HCl
S2Cl+2.5H₂+4O₂→2H₂SO₄+HCl
SCl₂+2H₂+2O₂→H₂SO₄+2HCl

These are but a few examples of the many reactions by which mixed acids can be generated in accordance with the invention. Including more H₂ and O₂ in the reactions will allow steam to be generated in addition to the mixtures of acids.

In order to devolitize the various resultant products of the reaction of HCl, HF, H₂SO₄ or HNO₃, either H₂O or H₂ and O₂ can be co-injected into the radical source 11 to form steam so that the solvating action of water will disperse in solution in the products. The temperature of the water must be cool enough so that a thin film of water will condense on the surface of the wafer 31. Raising the temperature of the water will evaporate the water solution, and spinning the wafer 31 will further assist in the removal process.

### Native Oxide Removal

The native oxide is ever present when a silicon wafer is exposed to oxygen (e.g., the atmosphere). The native oxide can be selectively eliminated by a combination of HF and steam formed by adding a fluorine source such as NF₃ or CF₄ to the reagent gases H₂ and O₂. In order for the native oxide elimination to be most effective, the reaction chamber should be maintained at a pressure below one about atmosphere.

### Photoresist Stripping

H₂ and O₂ can also be reacted to form steam for use in the stripping of photoresist which is commonly used in patterning of silicon wafers in the manufacture of integrated circuits. In addition, one or more other components such as HF, H₂SO₄and HNO₃ which are also generated with the radical source 11 can be used in varying combinations with the steam to effectively remove photoresist from the surface of the wafer 33. Hard implanted photoresist as well as residues in vias can also be removed with steam in combination with acids described herein.

SO₃ for use in the stripping of organic photoresist can be generated by adding O₂ to SO₂. Similarly, as discussed above, N₂O can be converted to NO₂, a strong oxidizing agent which can also be used in the stripping of photoresist.

Hydrofluoric acid can be used for stripping photoresist. The chemical generator 11 can generate hydrofluoric acid in situ in accordance with any of the following exemplary reactions:
CF₄+2H₂+O₂→CO₂+4HF
CF₄+1.5O₂+3H₂→CO₂+4HF+H₂O
NF₃+O₂+5H₂→N₂+6HF+2H₂O

Any of the operations described herein that form part of the invention are useful machine operations. The invention also relates to a device or an apparatus for performing these operations. The apparatus may be specially constructed for the required purposes, or it may be a general-purpose computer selectively activated or configured by a computer program stored in the computer. In particular, various general-purpose machines may be used with computer programs written in accordance with the teachings herein, or it may be more convenient to construct a more specialized apparatus to perform the required operations.

The invention can also be embodied as computer readable code on a computer readable medium. The computer readable medium is any data storage device that can store data that can thereafter be read by a computer system. Examples of the computer readable medium include hard drives, network attached storage (NAS), read-only memory, random-access memory, CD-ROMs, CD-Rs, CD-RWs, magnetic tapes, and other optical and non-optical data storage devices. The computer readable medium can also be distributed over a network coupled computer systems so that the computer readable code is stored and executed in a distributed fashion.

It will be further appreciated that the instructions represented by the operations in the above figures are not required to be performed in the order illustrated, and that all the processing represented by the operations may not be necessary to practice the invention. Further, the processes described in any of the above figures can also be implemented in software stored in any one of or combinations of the RAM, the ROM, or the hard disk drive.

Although the foregoing invention has been described in some detail for purposes of clarity of understanding, it will be apparent that certain changes and modifications may be practiced within the scope of the appended claims. Accordingly, the present embodiments are to be considered as illustrative and not restrictive, and the invention is not to be limited to the details given herein, but may be modified within the scope and equivalents of the appended claims.

What is claimed is:

1. A method of removing impurities in a film comprising:
generating hydrogen radicals including:
inputting a hydrogen radical precursor material to a radical source including a plasma chamber, that is external to a processing chamber, the radical source having an outlet in fluid communication with the processing chamber; and
creating a plasma in the plasma chamber;
inputting the hydrogen radicals into the processing chamber from the outlet of the radical source, wherein the processing chamber has a pressure of between about 1 millitorr and about 10 torr; and
exposing an impurity-containing film on a target to the hydrogen radicals.

2. The method of claim 1, wherein the surface of the target has a temperature of between about 50 degrees C. and about 500 degrees C.

3. The method of claim 1, wherein the surface of the target has a temperature of less than about 200 degrees C.

4. The method of claim 1, wherein inputting the hydrogen radicals into the processing chamber includes cooling the hydrogen radicals.

5. The method of claim 1, wherein the hydrogen radicals are input into the processing chamber at a flow rate of between about 50 sccm and about 3000 sccm.

6. The method of claim 1, wherein the outlet of the radical source is less than about 40 cm from the surface of the target.

7. The method of claim 1, wherein inputting the hydrogen radicals into the processing chamber includes substantially directing the hydrogen radicals toward the impurity-containing film on the target.

8. The method of claim 1, wherein inputting the hydrogen radicals into the processing chamber includes substantially evenly dispersing the hydrogen radicals over the impurity-containing film on the target.

9. The method of claim 1, wherein the impurity in the impurity-containing film includes at least one oxide and wherein exposing an impurity-containing film on the target to the hydrogen radicals includes reducing the oxygen from the oxide.

10. The method of claim 1, wherein the impurity-containing film includes at least one of sulfur or a sulfur-containing compound, and exposing an impurity-containing film on the target to the hydrogen radicals includes substantially removing the at least one of the sulfur or the sulfur-containing compound.

11. The method of claim 1, wherein the impurity-containing film includes at least one of chlorine or a chlorine-containing compound, and wherein exposing an impurity-containing film on the target to the hydrogen radicals includes substantially removing the at least one of the chlorine or the chlorine-containing compound.

12. The method of claim 1, wherein the impurity-containing film includes at least one of fluorine or a fluorine-containing compound, and wherein exposing an impurity-containing film on the target to the hydrogen radicals includes substantially removing the at least one of the fluorine or the fluorine-containing compound.

13. The method of claim 1, wherein the impurity-containing film has a thickness of between 0 and about 500 angstroms.

14. The method of claim 1, wherein the impurity-containing film on the target is exposed to the hydrogen radicals for a time interval of between less than about 30 seconds to about 2 hours.

15. The method of claim 1, wherein the target is a semiconductor wafer.

16. The method of claim 1, wherein the impurity -containing film includes at least one of a copper or a copper alloy.

17. The method of claim 1, wherein the impurity-containing film includes a metal oxide.

18. A system for removing impurities in impurity-containing film comprising:
a processing chamber for processing at least one target, the target having an exposed impuriiy-containing film;
a radical source, the radical source being external from the processing chamber, the radical source including an inlet, a plasma chamber and an outlet, the outlet being fluidly coupled to the processing chamber;
at least one precursor source coupled to the inlet of the radical source;
a controller coupled to the radical source and the processing chamber, the controller including:
computer readable code for generating hydrogen radicals in the radical source including:
computer readable code for inputting a hydrogen radical precursor material from the at least one precursor source to the plasma chamber;
computer readable code for creating a plasma in the plasma chamber; and
computer readable code for inputting the hydrogen radicals into the processing chamber from the outlet of the plasma chamber, wherein the processing chamber has a pressure of between about 1 millitorr and about 10 torr; and
computer readable code for exposing the impurity-containing film on the target to the hydrogen radicals.

19. The system of claim 18, wherein the surface of the target has a temperature of between about 50 degrees C. and about 500 degrees C.

20. The system of claim 18, wherein the surface of the target has a temperature of less than about 200 degrees C.

21. The system of claim 18, wherein the hydrogen radicals are input into the processing chamber at a flow rate of between about 50 sccm and about 3000 sccm.

22. The system of claim 18, wherein the outlet of the radical source is less than about 40 cm from the oxide-containing film on the target.

23. The system of claim 18, wherein inputting the hydrogen radicals into the processing chamber includes substantially directing the hydrogen radicals toward the impurity-containing film on the target.

24. The system of claim 18, wherein inputting the hydrogen radicals into the processing chamber includes substantially evenly dispersing the hydrogen radicals over the impurity-containing film on the target.

25. The system of claim 18, wherein the impurity in the impurity-containing film includes at least one oxide and wherein exposing an impurity-containing film on the target to the hydrogen radicals includes reducing the oxygen from the oxide.

26. The system of claim 18, wherein the impurity in the impurity-containing film includes at least one of sulfur, a sulfur-containing compound, and exposing the impurity-containing film on the target to the hydrogen radicals includes substantially removing the at least one of the sulfur or the sulfur-containing compound in the impurity-containing film.

27. The system of claim 18, wherein the impurity in the impurity-containing film includes at least one of chlorine or a chlorine-containing compound, and exposing the impurity-containing film on the target to the hydrogen radicals includes substantially removing the at least one of the chlorine or the chlorine-containing compound in the impurity-containing film.

28. The system of claim 18, wherein the impurity in the impurity-containing film includes at least one of fluorine or a fluorine-containing compound, and exposing the impurity-containing film on the target to the hydrogen radicals includes substantially removing the at least one of the fluorine or the fluorine-containing compound in the impurity-containing film.

29. The system of claim 18, wherein the oxide layer has a thickness of between 0 and about 500 angstroms.

30. The system of claim 18, wherein the surface of the target is exposed to the hydrogen radicals for a time interval of between less than about 30 seconds to about 2 hours.

31. The system of claim 18, wherein the radical source includes:
a first plasma chamber including a first input coupled to a first one of the at least one precursor source and a first outlet coupled to the outlet of the radical source;
a second plasma chamber, the second plasma chamber being concentrically about the first plasma generating chamber and including a second input coupled to a second one of the at least one precursor source and a second outlet coupled to the outlet of the radical source;
an induction coil disposed concentrically around the first plasma chamber and the second plasma generating chamber; and
an RF generator coupled to the induction coil.

32. The system of claim 18, wherein the target is a semiconductor wafer.

33. The system of claim 18, wherein the impurity-containing film includes at least one of a copper oxide or an oxide of a copper alloy.

34. The system of claim 18, wherein the impurity-containing film includes a metal oxide.

35. A method of reducing oxide in an exposed surface comprising:
generating hydrogen radicals including:
inputting a hydrogen radical precursor material to a radical source including a plasma chamber, that is external to a processing chamber, the radical source having an outlet in fluid communication with the processing chamber; and
creating a plasma in the plasma chamber;
inputting the hydrogen radicals into the processing chamber from the outlet of the radical source, wherein the outlet of the radical source is less than about 40 cm from the surface of the target, wherein the processing chamber has a pressure of between about 1 millitorr and about 10 torr;
exposing a surface of a target to the hydrogen radicals, the surface of the target having an oxide-containing film, wherein the oxide-containing film includes at least one of a copper oxide or an oxide of a copper alloy, wherein the surface of the target has a temperature of between about 50 degrees C. and about 500 degrees C.; and
reducing the oxygen from the oxide-containing film.

36. The method of claim 34, wherein inputting the hydrogen radicals into the processing chamber includes substantially evenly dispersing the hydrogen radicals over the oxide-containing film on the target.
